(19) United States
(12) Patent Application Publication
(10) Pub. No.: US 2017/0212150 A1
(43) Pub. Date: Jul. 27, 2017

(54) SHUNT RESISTOR AND SHUNT RESISTOR ASSEMBLY

(71) Applicant: SMART ELECTRONICS INC., Ulsan (KR)

(72) Inventors: Doo Won KANG, Anyang-si, Gyeonggi-do (KR); Hyun Chang KIM, Ulsan (KR); Kyung Mi LEE, Ulsan (KR); Hwang Je MUN, Busan (KR); A Lam SHIN, Yangsan-si, Gyeongsangnam-do (KR); Tae Hun KANG, Yangsan-si, Gyeongsangnam-do (KR)

(21) Appl. No.: 15/039,354

(22) PCT Filed: Dec. 16, 2013
(86) PCT No.: PCT/KR2013/011655

§ 371 Date: May 25, 2016

(30) Foreign Application Priority Data
Nov. 26, 2013 (KR) 10-2013-0144528

(51) Int. Cl. G01R 15/14

(52) U.S. Cl. CPC G01R 15/146

(57) ABSTRACT

Disclosed are a shunt resistor and a shunt resistor assembly in which measurement terminals to measure voltage are disposed as close as possible to a resistor element so as to reduce a measurement error, and mechanical and electrical connection is excellent.

### TECHNICAL FIELD

The present invention relates to a shunt resistor and a shunt resistor assembly, and more particularly to a shunt resistor and a shunt resistor assembly in which measurement terminals to measure voltage are disposed as close as possible to a resistor element so as to reduce a measurement error, and mechanical and electrical connection is excellent.

### BACKGROUND ART

In general, a shunt resistor used to detect current is used as a divided resistor when DC high current is measured, and may use low resistance less than 1 Ω so as to prevent voltage drop and power loss.

Shunt resistors include a non-inductive wire wound resistor (PRN), a super-mini wire wound resistor (SMW), a non-inductive metal plate resistor (MPR), a current sensing resistor (CSR), and a high current sensing resistor (CSR).

Among these shunt resistors, the high CSR serves to precisely measure voltage, current, and temperature of a vehicle battery, to predict charging state, aging state, and startability of the battery, and to transmit state information of the battery to an electronic control unit (ECU) to normally operate various devices connected to the battery.

Korean Patent Laid-open Publication No. 10-2012-0047925 discloses a low resistive current sensitive resistor 1.

FIG. 10 is a cross-sectional view illustrating a conventional shunt resistor. With reference to FIG. 10, the low resistive current sensitive resistor includes at least one plate-shaped connection part 2 and 3 and at least one contact point 7 and 8 for contact of the at least one plate-shaped connection part 2 and 3, and the at least one contact point 7 and 8 is formed by embossed regions of the at least one plate-shaped connection part 2 and 3. Here, two contact points 7 and 8 serve to measure voltage dropped throughout a resistor element.

However, in the above Korean Patent, since the embossing region includes a through hole, the contact points should be separated from the resistor element and thus, a voltage measurement error is generated as much as the separation distance.

### DISCLOSURE

### Technical Problem

Therefore, the present invention has been made in view of the above problems, and it is an object of the present invention to provide a shunt resistor and a shunt resistor assembly in which measurement terminals to measure voltage are disposed as close as possible to a resistor element so as to reduce a measurement error.

It is another object of the present invention to provide a shunt resistor and a shunt resistor assembly in which measurement terminals are bent and connected to one surface of connection pieces so that the shunt resistor and the shunt resistor assembly may be easily manufactured as compared to a conventional shunt resistor provided with through holes.

It is yet another object of the present invention to provide a shunt resistor and a shunt resistor assembly in which mechanical and electrical connection is excellent.

### Technical Solution

In accordance with an aspect of the present invention, the above and other objects can be accomplished by the provision of a shunt resistor including a resistor element, first and second connection pieces bonded to both sides of the resistor element, and first and second measurement terminals combined with the upper surfaces of the first and second connection pieces, wherein each of the first and second measurement terminals includes a base part bonded to one surface of each of the first and second connection pieces, and a measurement protrusion formed integrally with the base part and bent upwardly from the base part.

The measurement protrusion may include a support part extending from the base part and having a narrower width than that of the base part, and a connection terminal part extending from the support part and having a narrower width than that of the support part.

A receiving groove may be formed on one surface of each of the first and second connection pieces so as to receive the base part of each of the first and second measurement terminals.

Stepwise parts may be formed at bonding regions between the resistor element and the first and second connection pieces so that the upper surface of the resistor element is lower than the upper surfaces of the first and the second connection pieces.

The measurement protrusion may be bent at a region close to the resistor element.

In accordance with another aspect of the present invention, there is provided a shunt resistor assembly including a shunt resistor including a resistor element, first and second connection pieces bonded to both sides of the resistor element, and first and second measurement terminals combined with the upper surfaces of the first and second connection pieces, each of the first and second measurement terminals including a base part bonded to the inner end of each of the first and second connection pieces and a measurement protrusion formed integrally with the base part and bent upwardly from the base part, and a circuit unit combined with the shunt resistor and measuring current using a difference between voltages detected through the first and second measurement terminals.

The circuit unit may include a casing combined with the shunt resistor, a substrate accommodated within the casing, and a measurement unit mounted on the substrate.

The measurement protrusion may include a support part extending from the base part and having a narrower width than that of the base part, and a connection terminal part extending from the support part and having a narrower width than that of the support part.

The casing may be combined with the shunt resistor through insert injection molding, the support part of the measurement protrusion may be buried by the casing and only the connection terminal part of the measurement protrusion may be exposed to the outside of the casing, and the measurement protrusion may be assembled with the substrate under the condition that the measurement protrusion is inserted into the substrate, and is connected to the measurement unit.

### Advantageous Effects

As described above, a shunt resistor and a shunt resistor assembly in accordance with the present invention allow measurement terminals measuring voltage to be disposed as close as possible to a resistor element so as to reduce a measurement error.

Further, the shunt resistor and the shunt resistor assembly in accordance with the present invention allow the measurement terminals to be bent and be connected to one surface of connection pieces so that the shunt resistor and the shunt resistor assembly may be easily manufactured as compared to a conventional shunt resistor provided with through holes.

Further, the shunt resistor and the shunt resistor assembly in accordance with the present invention have excellent mechanical and electrical connection.

### DESCRIPTION OF DRAWINGS

The above and other objects, features and other advantages of the present invention will be more clearly understood from the following detailed description taken in conjunction with the accompanying drawings, in which:

FIG. 1 is a perspective view illustrating a shunt resistor in accordance with one embodiment of the present invention;

FIG. 2A is a cross-sectional view of FIG. 1, taken along the line A-A;

FIG. 2B is a cross-sectional view illustrating arrangement of first and second measurement terminals at the ends of first and second connection pieces in FIG. 2A;

FIG. 3A is a development view of the measurement terminal in accordance with the preset invention;

FIG. 3B is a perspective view illustrating bending of the measurement terminal of FIG. 3A;

FIG. 3C is a cross-sectional view illustrating soldering of the measurement terminal in accordance with the present invention in a receiving groove;

FIGS. 4 and 5 are cross-sectional views illustrating omission of stepwise parts and receiving grooves formed between the first and second connection pieces and a resistor element in the shunt resistor of FIG. 2A;

FIG. 6 is a perspective view illustrating combination of a casing with the shunt resistor in accordance with the present invention;

FIG. 7 is a cross-sectional view of FIG. 6, taken along the line B-B;

FIG. 8 is a cross-sectional view of a shunt resistor assembly in accordance with one embodiment of the present invention;

FIG. 9 is a cross-sectional view illustrating a process of measuring current of a battery using the shunt resistor assembly in accordance with the present invention; and

FIG. 10 is a cross-sectional view illustrating a conventional shunt resistor.

### BEST MODE

Hereinafter, preferred embodiments of the present invention will be described in detail with reference to the annexed drawings.

In the following description of the present invention, a detailed description of known functions and configurations incorporated herein will be omitted when it may make the subject matter of the present invention rather unclear. In addition, the terms used in the following description are terms defined taking into consideration the functions obtained in accordance with the present invention. The definitions of these terms should be determined based on the whole content of this specification because they may be changed in accordance with the intention of a user or operator or a usual practice.

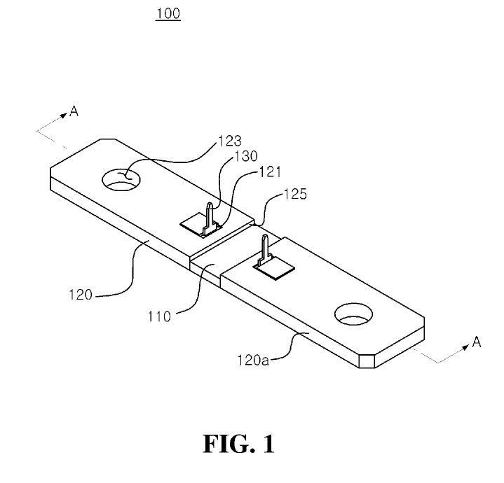

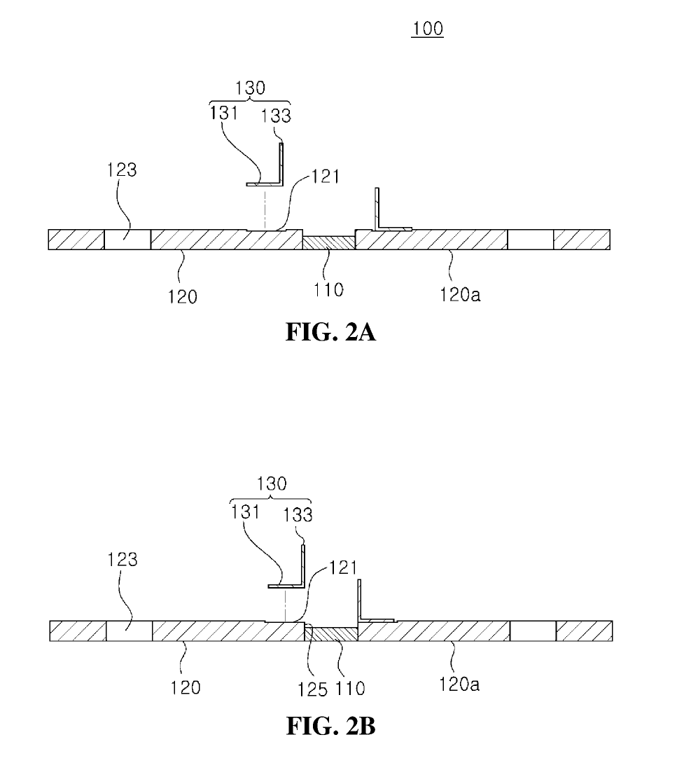

With reference to FIGS. 1 to 2B, a shunt resistor 100 in accordance with the present invention serves to measure current, for example, battery current and includes first and second connection pieces 120 and 120a, a resistor element 110, and first and second measurement terminals 130 and 130a.

The first connection piece 120 serves to introduce current to be measured into the shunt resistor 100, and the second connection piece 120a serves to discharge the current to be measured from the shut resistor 100. For example, the first and second connection pieces 120 and 120a may be formed in a plate shape.

Each of the first and second connection pieces 120 and 120a is formed of a conductive material, for example, copper, and is provided with a through hole 123 for electrical connection and a receiving groove 122 to receive the first or second measurement terminal 130 or 130a.

The resistor element 110 is disposed between the first and second connection pieces 120 and 120a and causes voltage drop. For example, the resistor element 110 is formed of a low resistance material having greater specific resistance than the first and second connection pieces 120 and 120a, particularly, an alloy including Cu, Mn, or Ni.

The resistor element 110 and the first and second connection pieces 120 and 120a may be combined through welding, for example, laser welding or electron beam welding.

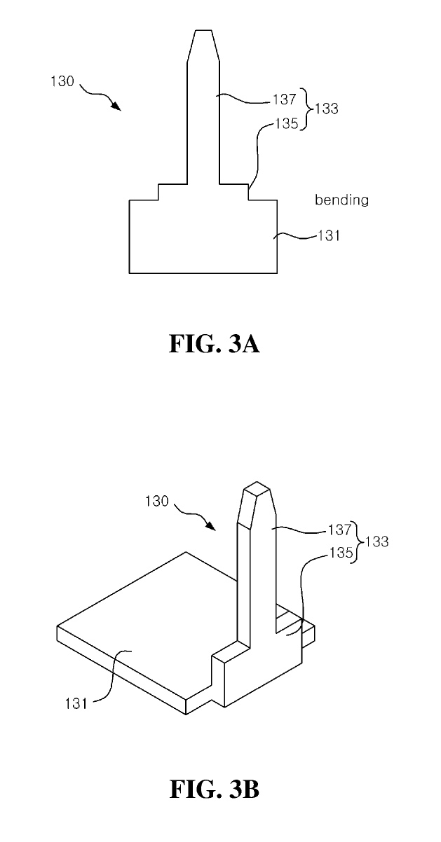

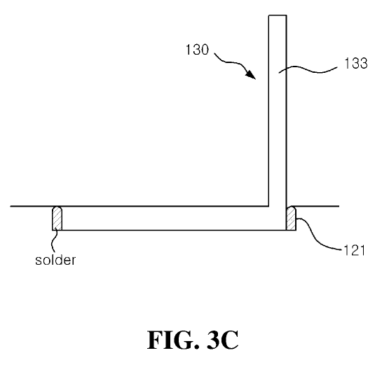

With reference to FIGS. 3A to 3C, the first and second measurement terminals 130 and 130a serve to measure voltage dropped throughout the resistor element 110, and are combined with the first and second connection pieces 120 and 120a.

The first and second measurement terminals 130 and 130a may be disposed close to the resistor element 110 so as to reduce a measurement error of voltage.

For example, each of the first and second measurement terminals 130 and 130a may include a base part 131 bonded to one surface of each of the first and second connection pieces 120 and 120a, and a measurement protrusion 133 formed integrally with the base part 131 and bent upwardly from the base part 131.

The base part 131 is formed in a plate shape broader than the measurement protrusion 133, and thus enhancement in mechanical combining force may be expected. The base part 131 may be combined with each of the first and second measurement terminals 130 and 130a through soldering.

The measurement protrusion 133 is connected to a circuit unit, which will be described later, and detects voltage of a corresponding region.

The measurement protrusion 133 may include a support part 135 extending from the base part 131 and having a narrower width than that of the base part 131, and a connection terminal part 137 extending from the support part 135 and having a narrower width than that of the support part 135.

The measurement protrusion 133 is bent at a region close to the resistor element 110.

The support part 135 has a wider width than that of the connection terminal part 137, and may thus serve to prevent breakage of a bending region during bending of the measurement protrusion 133 and to support a substrate, which will be described later.

Further, a receiving groove 121 is formed on one surface of each of the first and second connection pieces 120 and 120a so as to receive the base part 131 of each of the first and second measurement terminals 130 and 130a.

If the first and second measurement terminals 130 and 130a are soldered within the receiving grooves 121, not only the lower surfaces of the base parts 131 but also the side surfaces of the receiving grooves 121 and the side surfaces of the base parts 131 are soldered and thus, combining force may be improved.

Further, the receiving grooves 121 guide the combining positions of the first and second measurement terminals 130 and 130a with the first and second connection pieces 120 and 120a, thus lowering a defect rate.

Further, stepwise parts 125 may be formed at bonding regions between the resistor element 110 and the first and second connection pieces 120 and 120a.

In more detail, the stepwise parts 125 may be configured so that the upper surface of the resistor element 110 is lower than the upper surfaces of the first and the second connection pieces 120 and 120a.

By forming the stepwise parts 125 between the first and second connection pieces 120 and 120a and the resistor element 110, the first and second measurement terminals 130 and 130a may be located as close as possible to the resistor element 110.

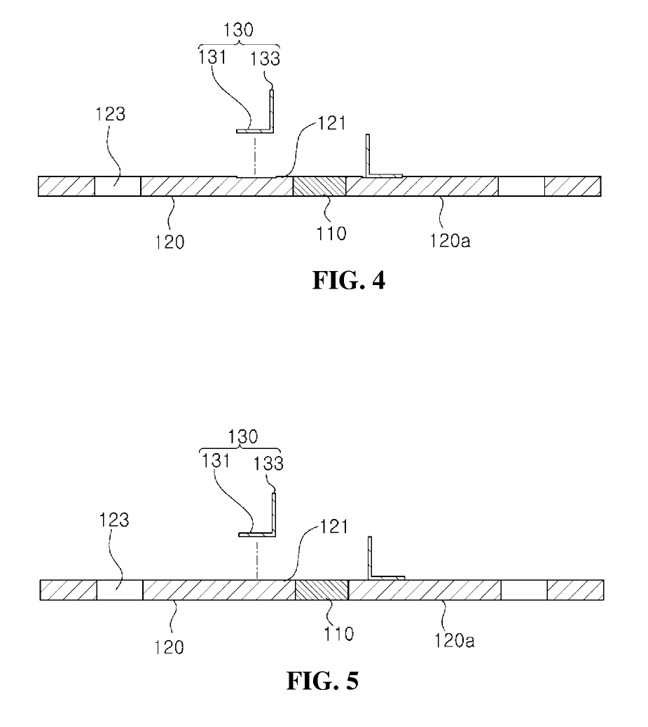

That is, if the stepwise parts 125 are not formed between the first and second connection pieces 120 and 120a and the resistor element 110, as exemplarily shown in FIG. 4, in order to prevent contact between the first and second measurement terminals 130 and 130a and the resistor element 110, the first and second measurement terminals 130 and 130a need to be separated from the ends of the first and second connection pieces 120 and 120a by a designated distance.

On the other hand, if the stepwise parts 125 are formed between the first and second connection pieces 120 and 120a and the resistor element 110, as exemplarily shown in FIG. 2B, although the first and second measurement terminals 130 and 130a are arranged at the ends of the first and second connection pieces 120 and 120a, the first and second measurement terminals 130 and 130a do not contact the resistor element 110 by the stepwise parts 125 and thus, a measurement error of voltage drop may be maximally reduced.

Hereinafter, a shunt resistor assembly in accordance with the present invention will be described in detail with reference to the accompanying drawings. However, among constituent elements of the shunt resistor assembly, the shunt resistor has been described above and a detailed description thereof will thus be omitted.

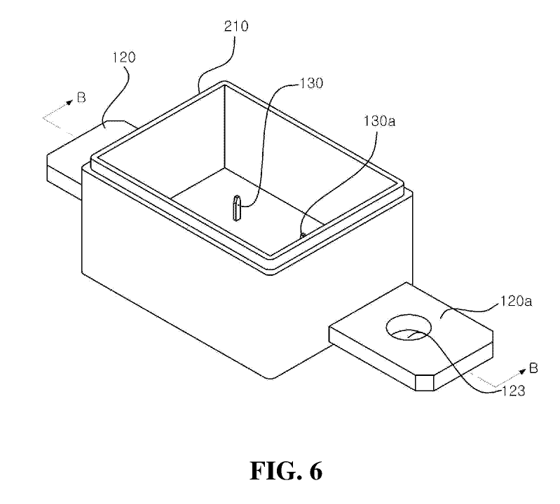

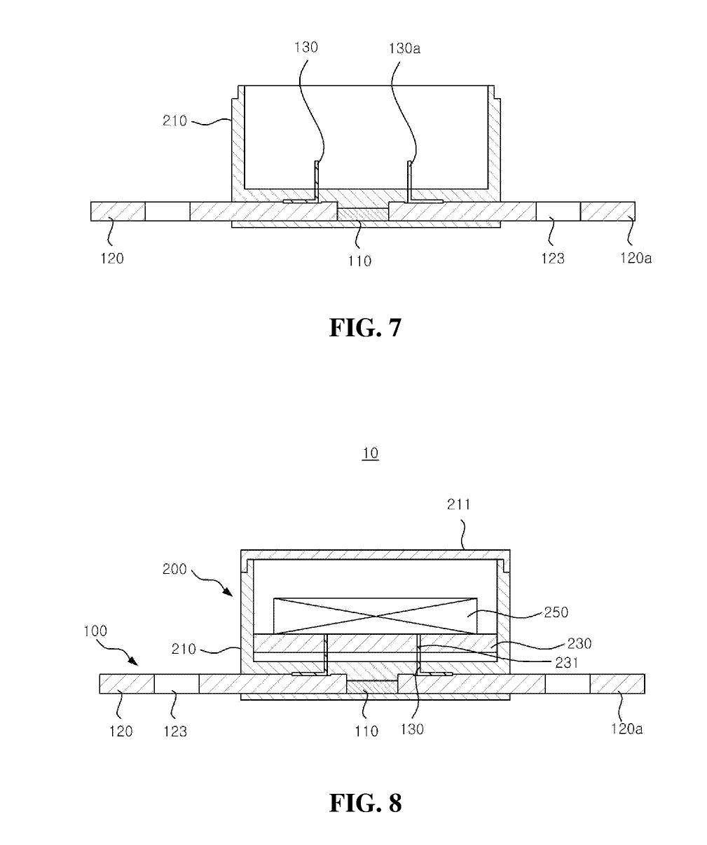

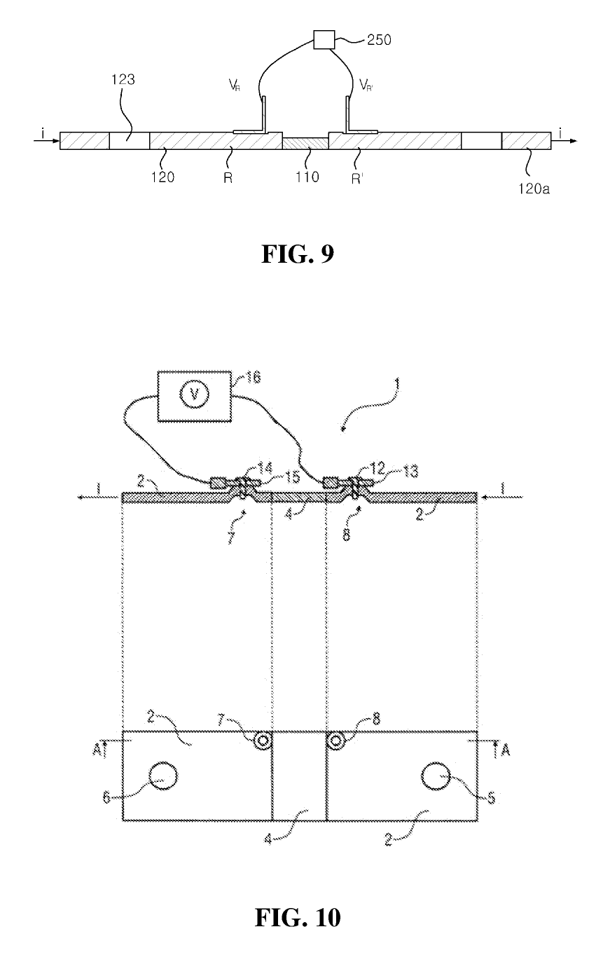

With reference to FIGS. 6 to 9, a shunt resistor assembly 10 in accordance with the present invention may include the above-described shunt resistor 100, and a circuit unit 200 combined with the shunt resistor assembly 100 and measuring current of a battery using a difference between voltage values detected through the first and second measurement terminals 130 and 130a.

The circuit unit 200 may include a casing 210 combined with the shunt resistor 100, a substrate 230 accommodated within the casing 210 and provided with a circuit pattern, and a measurement unit 250 mounted on the substrate 230.

The casing 210 has a box shape provided with an inner space to accommodate the substrate 230 and the circuit unit 200, and a lid 211 to open and close the casing 210 may be formed.

The casing 210 is combined with the shunt resistor 100 through insert injection molding, and the entirety of the resistor element 110 and parts of the first and second connection pieces 120 and 120a are buried by the casing 210.

Through insert injection molding, the connection terminal parts 137 of the measurement protrusions 133 are exposed to the inner space of the casing 210 and the support parts 135 are buried by the casing 210

The exposed connection terminal parts 137 are soldered under the condition that the exposed connection terminal parts 137 are inserted into coupling holes 231 formed through the substrate 230, and are thus connected to the measurement unit 250.

The substrate 230 is provided with the coupling holes 231 corresponding to the connection terminal parts 137 of the first and second measurement terminals 130 and 130a.

The connection terminal parts 137 are assembled with the substrate 230 by inserting the connection terminal parts 137 into the coupling holes 231, and are connected to the measurement unit 250 through the circuit pattern formed on the substrate 230.

The measurement unit 250 serves to measure voltage values V_{R} and V_{R′} and to convert the measured voltage values V_{R} and V_{R′} into a current value i.

In more detail, the measurement unit 250 acquires the current value i of a battery through calculation using the measured voltage values V_{R} and V_{R′}, detected through the respective measurement terminals 130 and 130a, and resistance values R and R′, input in advance, based on the Ohm's law (V=iR).

### Mode for Invention

Various embodiments have been described in the best mode for carrying out the invention.

### INDUSTRIAL APPLICABILITY

As apparent from the above description, a shunt resistor and a shunt resistor assembly in accordance with the present invention allow measurement terminals measuring voltage to be disposed as close as possible to a resistor element so as to reduce a measurement error, and have excellent mechanical and electrical connection.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A shunt resistor comprising:
a resistor element;
first and second connection pieces bonded to both sides of the resistor element; and
first and second measurement terminals combined with the upper surfaces of the first and second connection pieces,
wherein each of the first and second measurement terminals includes a base part bonded to one surface of each of the first and second connection pieces, and a measurement protrusion formed integrally with the base part and bent upwardly from the base part.

2. The shunt resistor according to claim 1, wherein the measurement protrusion includes a support part extending from the base part and having a narrower width than that of the base part, and a connection terminal part extending from the support part and having a narrower width than that of the support part.

3. The shunt resistor according to claim 1, wherein a receiving groove is formed on one surface of each of the first and second connection pieces so as to receive the base part of each of the first and second measurement terminals.

4. The shunt resistor according to claim 1, wherein stepwise parts are formed at bonding regions between the resistor element and the first and second connection pieces so that the upper surface of the resistor element is lower than the upper surfaces of the first and the second connection pieces.

5. The shunt resistor according to claim 1, wherein the measurement protrusion is bent at a region close to the resistor element.

6. A shunt resistor assembly comprising:
a shunt resistor including a resistor element, first and second connection pieces bonded to both sides of the resistor element, and first and second measurement terminals combined with the upper surfaces of the first and second connection pieces, each of the first and second measurement terminals including a base part bonded to the inner end of each of the first and second connection pieces and a measurement protrusion formed integrally with the base part and bent upwardly from the base part; and
a circuit unit combined with the shunt resistor and measuring current using a difference between voltages detected through the first and second measurement terminals.

7. The shunt resistor assembly according to claim 6, wherein the circuit unit includes:
a casing combined with the shunt resistor;
a substrate accommodated within the casing; and
a measurement unit mounted on the substrate.

8. The shunt resistor assembly according to claim 7, wherein the measurement protrusion includes a support part extending from the base part and having a narrower width than that of the base part, and a connection terminal part extending from the support part and having a narrower width than that of the support part.

9. The shunt resistor assembly according to claim 8, wherein:
the casing is combined with the shunt resistor through insert injection molding;
the support part of the measurement protrusion is buried by the casing and only the connection terminal part of the measurement protrusion is exposed to the outside of the casing; and
the measurement protrusion is assembled with the substrate under the condition that the measurement protrusion is inserted into the substrate, and is connected to the measurement unit.
